(19) United States
(12) Patent Application Publication
(10) Pub. No.: US 2013/0314961 A1
(43) Pub. Date: Nov. 28, 2013

(54) SWITCH CONTROL DEVICE, POWER SUPPLY DEVICE COMPRISING THE SAME, AND DRIVING METHOD OF POWER SUPPLY DEVICE

(71) Applicant: FAIRCHILD KOREA SEMICONDUCTOR LTD., Bucheon (KR)

(72) Inventors: Hyun-Chul EOM, Seoul (KR); Seung-Uk YANG, Anyang-si (KR)

(73) Assignee: FAIRCHILD KOREA SEMICONDUCTOR LTD., Bucheon (KR)

(21) Appl. No.: 13/901,792

(22) Filed: May 24, 2013

(30) Foreign Application Priority Data
May 25, 2012 (KR) 10-2012-0056349

(51) Int. Cl. H03K 3/015; H02M 7/217

(52) U.S. Cl. CPC H03K 3/015; H02M 7/217
USPC 363/89; 327/109

(57) ABSTRACT

The present invention relates to a switch controller, a power supply including the same, and a driving method thereof. An AC input of the power supply is connected to a rectification circuit. The power supply includes a power switch to which the AC input passed through the rectification circuit flows during a turn-on period of the power switch and a switch controller detecting a half-on time point that is an intermediate time point of the turn-on period, calculating the AC current using a result of sampling a sense voltage that depends on a current flowing to the power switch during the turn-on period at the half-on time point and the turn-on period, and controlling the input current to have a reference sine wave. The reference sine wave has a sine wave that is full-wave rectified from the AC input.

### CROSS-REFERENCE TO RELATED APPLICATION

This application claims priority to and the benefit of Korean Patent Application No. 10-2012-0056349 filed in the Korean Intellectual Property Office on May 25, 2012, the entire contents of which are incorporated herein by reference.

### BACKGROUND OF THE INVENTION

(a) Field of the Invention

An exemplary embodiment of the present invention relates to a switch controller and a power supply including the same. In addition, an exemplary embodiment of the present invention relates to a driving method of the power supply.

(b) Description of the Related Art

FIG. 1 shows a conventional buck converter.

An LED string 4 is connected to the buck converter 1, and an AC input of the buck converter 1 is rectified through a rectification circuit 2.

For power factor correction, the buck converter 1 controls switching operation of a switch 6 such that a switch current I3 flowing to the switch 6 follows a sine wave. For example, during a turn-on period of the switch 6, as the switch current I3 increases and reaches a reference according to the sine wave, the switch 6 is turned off. In this case, a switching frequency is a fixed frequency.

An LED current (or, a current flowing to an inductor 5) flowing to the LED string 4 in the buck converter 1 flows through the switch 6 during a turn-on period of the switch 6. During this period, the input current I1, the LED current I2, and the switch current I3 all exist.

However, when the LED current I2 performs free-wheeling through the diode D3 during the turn-off period of the switch 6, the input current I1 and the switch current I3 do not exist during the turn-off period of the switch 6.

As previously stated, the input current I1 should be controlled to depend on the input voltage V1 for power factor correction. However, the power factor correction cannot be performed during the turn-off period of the switch 6 in the conventional buck converter 1 because the input current I1 does not exist during the period.

Furthermore, in a characteristic graph of the LED current I2 and the LED voltage V2, the LED voltage V2 hardly experiences variation although the LED current I2 is changed according to a full wave rectified sine wave. This is a cause that the input current I1 does not have a full wave rectified sine wave.

Input power is set to a product of the input voltage V1 and the input current I1, and output power is set to power supplied to the LED string 4. Then, the output power is a product of the LED current I2 and the LED voltage V2. In this case, it is assumed that all the input power is converted to output power.

The LED current I2 is controlled to the full-wave rectified sine wave, and the output voltage V2 has a constant value without being influenced by variation of the LED current I2. In this case, since the input voltage V1 has the full-wave rectified sine wave, the input current I1 maintains a constant value.

That is, the input current I1 does not depend on the input voltage V1, and accordingly the power factor correction cannot be performed.

The above information disclosed in this Background section is only for enhancement of understanding of the background of the invention and therefore it may contain information that does not form the prior art that is already known in this country to a person of ordinary skill in the art.

### SUMMARY OF THE INVENTION

The present invention has been made in an effort to provide a switch controller that can improve power factor correction, a switch controlling method, and a power supply including the switch controller.

A power supply according to an exemplary embodiment of the present invention includes: a rectification circuit connected to an AC input; a power switch to which the AC input passed through the rectification circuit flows during a turn-on period of the power switch; and a switch controller detecting a half-on time point that is an intermediate time point of the turn-on period, calculating the AC current using a result of sampling a sense voltage that depends on a current flowing to the power switch during the turn-on period at the half-on time point and the turn-on period, and controlling the input current to have a reference sine wave. The reference sine wave follows a sine wave that is full-wave rectified from the AC input.

The switch controller includes an input current calculation unit calculating the AC input using a half sense voltage generated by sampling the sense voltage at the half-on time point and the turn-on period.

The switch controller includes a half-on detection unit that samples a voltage that is the half of a voltage charged during a turn-on period in the previous switching cycle of the power switch as a half-on reference voltage and senses a time point that a voltage charged during a turn-on period of the present switching cycle reaches the half-on reference voltage as the half-on time point.

The half-on detection unit includes: a sampling/reset signal generation unit generating a sampling signal synchronized at a turn-off time point of the power switch to command sampling and a reset signal commanding reset; a charging unit generating an on-period voltage according to the turn-on period of the power switch; a sampling unit sampling the on-period voltage according the sampling signal and generating the half-on reference voltage by dividing the sampled voltage into the half; and a half-on pulse generation unit comparing the half-on reference voltage and the on-period voltage and generating a half-on pulse synchronized at a half-on time point according to the comparison result.

The sampling/reset signal generation unit includes: an inverter outputting an inverted level of a gate voltage that controls switching operation of the power switch; a first delay unit outputting the gate voltage by delaying for a predetermined first delay period; an AND gate generating a sampling signal by performing an AND operation on an output of the inverter and an output of the first delay unit; and a second delay unit outputting the sampling signal by delaying for a predetermined second delay period.

The charging unit includes: a capacitor; a current source generating a charging current; a charging switch connected between the current source and the capacitor and being turned on during the turn-on period of the power switch; and a reset switch connected to the capacitor in parallel and being switched according to the reset signal.

The sampling unit includes: a sampling switch being switched according to the sampling signal and transmitting the on-period voltage to a first node; a capacitor connected between the first node and a ground; and first and second resistors connected between the first node and the ground. A voltage of a second node to which the first resistor and the second resistor are connected is the half-on reference voltage.

The half-on pulse generation unit includes: a comparator outputting a result of comparison between the on-period voltage and the half-on reference voltage; an inverter outputting an inverted value of the output of the comparator; a delay unit outputting the output of the inverter by delaying for a third delay period; and an AND gate generating the half-on pulse by performing an AND operation on the output of the delay unit and the output of the comparator.

The switch controller further includes an input current calculation unit generating a half sense current that depends on a half sense voltage sampled from the sense voltage at every half-on time point and generating an input current indicating voltage indicating the input current using the half sense current during the turn-on period of the present switching cycle.

The input current calculation unit includes: a sampling unit synchronized at the half-on time point and generating the half sense voltage by sampling the sense voltage; a VI converter generating a half sense current by converting the half sense voltage; a charging unit generating the input current indicating voltage using the half sense current; and a current mirror circuit mirroring the half sense current and transmitting the mirrored current to the charging unit.

The sampling unit includes: a buffer transmitting the sense voltage; a capacitor; and a sampling switch connected between an output terminal of the buffer and the capacitor, and synchronized at the half-on time point to transmit the sense voltage to the capacitor, and a voltage charged in the capacitor is the half-on reference voltage.

The VI converter includes: an error amplifier including a first terminal to which the half sense voltage is input, a second terminal, and an output terminal; a resistor connected between the second terminal and the ground; and a transistor including a first electrode connected to the current mirror circuit, a second electrode connected to the second terminal of the error amplifier, and a gate electrode connected to the output terminal of the error amplifier.

The charging unit includes: a capacitor; a charging switch connected between the current mirror and the capacitor and being turned on during the turn-on period of the power switch; and a reset switch connected to the capacitor in parallel and being switched according to the reset signal, and during the turn-on period of the charging switch, the capacitor is charged by the half sense current and a voltage charged in the capacitor is the input current indicating voltage.

The switch controller turns off the power switch at a time point that the input current indicating voltage reaches the reference sine wave.

The switch controller detects one cycle of the input voltage by sensing a zero voltage crossing time point of the input voltage and generating the reference sine wave that is a full wave rectified sine wave of the same cycle of one cycle of the input voltage.

A driving method of a power switch according to an exemplary embodiment of the present invention includes: flowing an input current through a power switch from an AC input during a turn-on period of the power switch; detecting a half-on time point that is an intermediate time point of the turn-on period; sampling a sense voltage that depends on the current flowing to the power switch as a half sense voltage at the half-on time point; calculating the input current using the turn-on period and the half sense voltage; and switching the power switch to control the calculated input current to have a reference sine wave that is a full wave rectified sine wave.

The detecting the half-on time point includes sampling a voltage that is the half of a voltage charged during a turn-on period of the previous switching cycle of the power switch as a half-on reference voltage and sensing a time point that a voltage charged during a turn-on period of the present switching cycle reaches the half-on reference voltage as the half-on time point.

The calculating the input current includes converting the half sense voltage into a half sense current and generating an input current indicating voltage indicating the input current by using the half sense current during the turn-on period of the present switching cycle.

A switch controller of a power supply converting an AC input according to switching operation of a power switch according to an exemplary embodiment of the present invention includes: a half-on detection unit sampling a voltage that the half of a voltage charged during a turn-on period of the previous switching cycle of the power switch as a half-on reference voltage and sensing a time point that a voltage charged during a turn-on period of the present switching cycle reaches the half-on reference voltage as the half-on time point; and an input current calculation unit calculating an input current of the AC input by multiplying the turn-on period of the present switching cycle to a half sense voltage that is sampled from the sense voltage at every half-on time point. The input current includes a current flowing through the power switch from the AC input during the turn-on period of the power switch.

The half-on detection unit includes: a sampling/reset signal generation unit synchronized at a turn-off time point of the power switch to generate a sampling signal that commands sampling and a reset signal that commands reset; a charging unit generating an on-period voltage that depends on the turn-on period of the power switch; a sampling unit sampling the on-period voltage according to the sampling signal and generating a half-on reference voltage by dividing the sampled voltage into the half; and a half-on pulse generation unit comparing the half-on reference voltage with the on-period voltage and generating a half-on pulse synchronized at a half-on time point according to the comparison result.

The input current calculation unit includes: a sampling unit being synchronized at the half-on time point to generate the half sense voltage by the sampling the sense voltage; a VI converter generating a half sense current by converting the half sense voltage; a charging unit generating the input current indicating voltage using the half sense current; and a current mirror circuit mirroring the half sense current and transmitting the mirrored current to the charging unit.

According to the exemplary embodiments of the present invention, a switch controller a switch controlling method, and a power supply including the switch controller can be provided.

### BRIEF DESCRIPTION OF THE DRAWINGS

FIG. 1 shows a conventional buck converter.

FIG. 2 illustrates a switch controller and a buck converter including the same according to an exemplary embodiment of the present invention.

FIG. 3 shows a half-on detection unit according to the exemplary embodiment of the present invention.

FIG. 4 shows a waveform diagram illustrating a gate voltage, a sampling signal, a reset signal, an on-period voltage, and a half-on pulse according to an exemplary embodiment of the present invention.

FIG. 5 shows an input current calculation unit according to the exemplary embodiment of the present invention.

FIG. 6 is a waveform diagram illustrating a gate voltage, a half-on pulse, a sense voltage, a reset pulse, and input voltage indication voltage according to the exemplary embodiment of the present invention.

FIG. 7 shows comparison between an input current according to a conventional art shown in FIG. 1 and an input current according to the exemplary embodiment of the present invention.

### DETAILED DESCRIPTION OF THE EMBODIMENTS

In the following detailed description, only certain exemplary embodiments of the present invention have been shown and described, simply by way of illustration. As those skilled in the art would realize, the described embodiments may be modified in various different ways, all without departing from the spirit or scope of the present invention. Accordingly, the drawings and description are to be regarded as illustrative in nature and not restrictive. Like reference numerals designate like elements throughout the specification.

Throughout this specification and the claims that follow, when it is described that an element is “coupled” to another element, the element may be “directly coupled” to the other element or “electrically coupled” to the other element through a third element. In addition, unless explicitly described to the contrary, the word “comprise” and variations such as “comprises” or “comprising”, will be understood to imply the inclusion of stated elements but not the exclusion of any other elements.

Hereinafter, an exemplary embodiment of the present invention will be described with reference to the accompanying drawings.

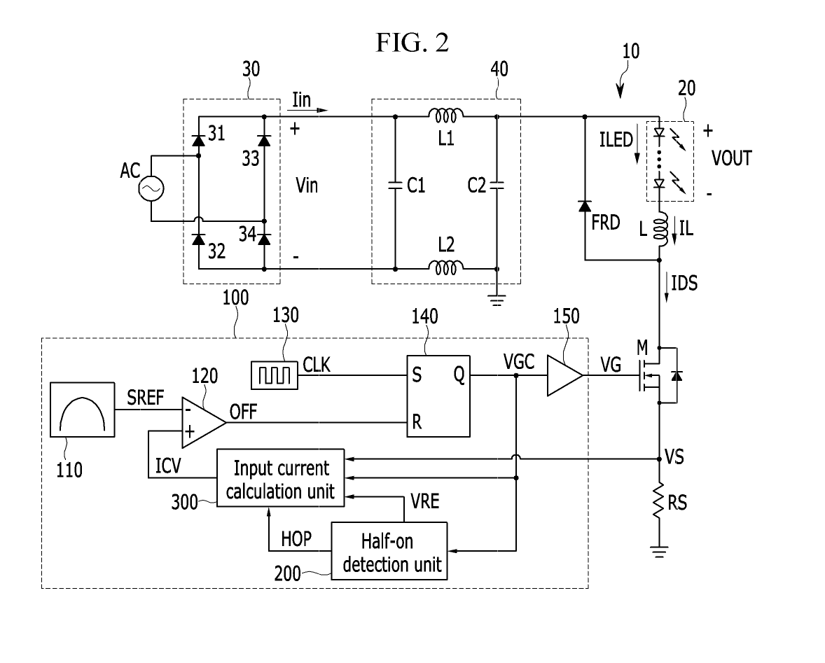

FIG. 2 shows a switch controller and a buck converter including the same according to the exemplary embodiment of the present invention. The buck converter 10 is connected to an LED string 20. The LED string 20 includes an LED element serially coupled to the LED string 20.

The buck converter 10 includes a rectification circuit 30, an EMI filter 40, a diode FRD, an inductor L, a power switch M, a sense resistor RS, and a switch controller 100.

The rectification circuit 30 is realized as a bridge diode, and includes four rectification diodes 31 to 34, two input terminals connected to an AC input AV, a first terminal connected to a ground, and a second terminal connected to the LED string 20.

The rectification circuit 30 generates an input voltage Vin by full-wave rectifying the AC input AC. The input voltage Vin is a full-wave rectification sine wave. During a turn-on period of the power switch M, a current generated from the AC input AC flows back to the AC input AC through the ground. The current is rectified through the rectification circuit 30 and then becomes an input current Iin.

The switch controller 100 calculates the input current Iin, and controls the input current Iin to follow the full-wave rectification sine wave. Then, a voltage and a current of the AC input AC become sine waves so that a power factor correction is performed.

The EMI filter 40 removes noise generated in a power line connected to the AC input AC through the rectification circuit 30 to protect an element or a circuit in the next stage. The EMI filter 40 includes two inductors L1 and L2 and two capacitors C1 and C2.

The inductor L1 includes a first terminal connected to the second terminal of the rectification circuit 30 and a second terminal connected to the LED string 20, the inductor L2 includes a first terminal connected to the first terminal of the rectification circuit 30 and a second terminal connected to the ground. The capacitor C1 is connected to the first terminal of the inductor L1 and the first terminal of the inductor L2, and the capacitor C2 is connected to the second terminal of the inductor L1 and the second terminal of the inductor L2.

The power switch M performs switching operation according to a gate signal VG transmitted from the switch controller 100. The power switch M is realized as an n-channel metal oxide semiconductor filed effect transistor (NMOSFET). The present invention is not limited thereto, and another type of transistor may be applied as necessary.

A first terminal of the LED string 20 is connected to an input voltage Vin through the EMI filter 40, and a second terminal of the LED string 20 is connected to the first terminal of the inductor L. As a fast recovery diode, the diode FRD is connected to a drain electrode of the power switch M and a first terminal of the LED string 20. During a turn-off period of the power switch M, a freewheeling current flowing to the inductor L flows through the diode FRD.

The drain electrode of the power switch M is connected to the second terminal of the inductor L, and a source electrode of the power switch M is connected to a first terminal of the sense resistor RS. The gate signal VG transmitted from the switch controller 100 is input to the gate electrode of the power switch M. The power switch M is switched by the gate signal VG.

When the power switch M is in the turn-on state, an inductor current IL increasing according to the input voltage Vin flows through the LED string 20 and the power switch M and energy is stored in the inductor L by the inductor current IL. In this case, a current flowing to the power switch M flows to a resistor RS such that a sense voltage VS is generated. Hereinafter, the current flowing to the power switch M is referred to as a drain current IDS.

When the power switch M is in the turn-off state, the inductor current IL is decreased for a period during the energy stored in the inductor L exits during the turn-on period of the power switch M. In this case, the decreasing inductor current flows to the LED string 20 through the diode FRD. The LED current ILED flowing to the inductor current and the LED current ILED flowing to the LED string 20 are the same. Hereinafter, the two currents are referred to as an LED current ILED.

During the turn-on period of the power switch M, the input current Iin flows back to the AC input AC through the power switch M and the ground from the AC input AC. In this case, the input current Iin, the LED current ILED, and the drain current IDS are equivalent to each other. During the turn-off period of the power switch M, the input current Iin and the drain current IDS are not generated, and the LED current ILED freewheels through the diode FRD.

The switch controller 100 detects a half-on time, that is, a middle time point of the turn-on period of the power switch M, calculates an input current Iin using the sense voltage VS at the half-on time, and controls the switching operation using the calculation result and a reference sine wave SREF.

The switch controller 100 detects the sense voltage VS at the half-on time, and generates an input current indication voltage ICV that indicates the input current Iin using the detected voltage and an on-time. Hereinafter, the sense voltage detected at the half-on time is referred to as a half sense voltage HVS.

The sense voltage VS is generated by the sense resistor RS that is provided to sense a drain current IDS, and therefore the input current Iin cannot be represented using only the sense voltage VS. The switch controller 100 generates an input current indicating voltage ICV according to a product of the half sense voltage HVS and the turn-on period of the power switch M for calculation of the input current Iin.

The switch controller 100 compares the input current indicating voltage ICV with a reference sine wave SREF, and turns off the power switch M the input current indicating voltage ICV reaches the reference sine wave SREF and turns on the power switch M at a rising edge time of a clock signal CLK that determines a switching frequency.

The switch controller 100 includes a sine wave generation unit 110, an off comparator 120, an oscillator 130, an SR flip-flop 140, a gate driving unit 150, a half-on detection unit 200, and an input current calculation unit 300.

The sine wave generation unit 110 senses a zero voltage crossing time of the input voltage Vin and detects one cycle of the input voltage Vin, and generates a reference sine wave SREF that is a full-wave rectification sine wave having a cycle that is the same as one cycle of the input voltage Vin.

The off comparator 120 compares the reference sine wave SREF with the input current indicating voltage ICV, and generates a high-level off signal OFF to turn off the power switch M at a time that the input current indicating voltage ICV reaches the reference sine wave SREF.

The reference sine wave SREF is input to an inversion terminal (−) of the off comparator 120, the input current indicating voltage ICV is input to a non-inversion terminal (+), and the off comparator 120 generates a high-level off signal OFF when an input of the non-inversion terminal (+) is higher than an input of the inversion terminal (−) and generates a low-level off signal OFF in the opposite case.

The oscillator 130 generates the clock signal CLK that determines a switching cycle of the power switch M.

The SR flip-flop 140 generates a gate control signal VGC that turns on the power switch M according to the clock signal CLK, and generates a gate control signal VGC that turns off the power switch M according to the off signal OFF. The SR flip-flop 140 includes a set terminal S to which the clock signal CLK is input and a reset terminal R to which the off signal OFF is input.

The SR flip-flop 140 generates a high-level gate control signal VGC when an input of the set terminal S is high level, and generates a low-level gate control signal VGC when an input of the reset terminal R is high level.

The gate driving unit 150 generates a gate voltage VG according to the gate control signal VGC. For example, the gate driving unit 150 generates a high-level (i.e., enable-level) gate voltage VG according to the high-level gate control signal VGC, and generates a low-level (i.e., disable-level) gate voltage VG according to the low-level gate control signal VGC.

The half-on detection unit 200 detects a half-on time according to a result of comparison between a voltage sampled by dividing a voltage charged during an on-period of the previous switching cycle into the half and a voltage charged during an on-period of the present switching cycle.

That is, a time that a voltage charged from a turn-on time point of the power switch M reaches to the half-on reference voltage HRV set during the previous switching cycle is detected as a half-on time of the present switching cycle.

The input current calculation unit 300 generates the half sense voltage HVS by sampling the sense voltage VS at the half-on time, and generates the input current indicating voltage ICV by charging a capacitor during the on-period with a current that depends on the half sense voltage HVS. That is, the input current calculation unit 300 charges the capacitor with the current that depends on the half sense voltage HVS during the on-period to calculate a product of the half sense voltage HVS and the on-period.

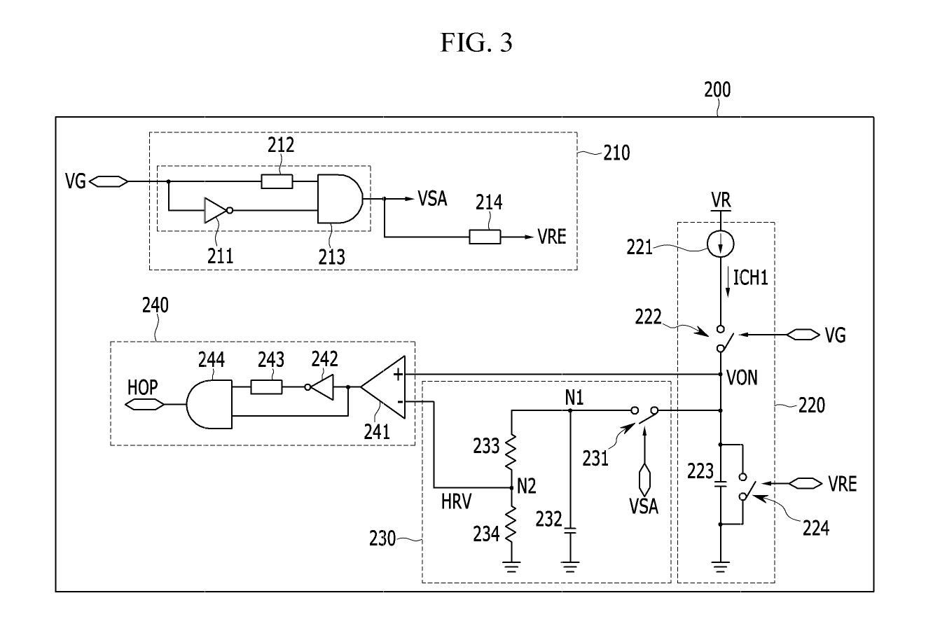

First, the half-on detection unit 200 will be described with reference to FIG. 3.

FIG. 3 shows the half-on detection unit according to the exemplary embodiment of the present invention.

As shown in FIG. 3, the half-on detection unit 200 includes a sampling/reset signal generation unit 210, a charging unit 220, a sampling unit 230, and a half-on pulse generation unit 240.

The sampling/reset signal generation unit 210 generates a sampling signal VSA that commands sampling and a reset signal VRE that commands reset by being synchronized at a turn-off time point of the power switch M. The sampling/reset signal generation unit 210 can sense the turn-off time point of the power switch M using the gate voltage VG.

The sampling/reset signal generation unit 210 includes an inverter 211, a delay unit 212, an AND gate 213, and a delay unit 214.

The inverter 211 outputs an inverse-level of the gate voltage VG. The inverter 211 outputs low level inverted from a high-level gate voltage VG, and outputs high level inverted from a low-level gate voltage VG.

The delay unit 212 receives the gate voltage VG, and outputs the gate voltage VG after delaying for a predetermined first delay period DL1.

The AND gate 213 receives the output of the inverter 211 and the output of the delay unit 212 and generates a sampling signal VSA by performing an AND operation on the inputs.

The delay unit 214 receives the sampling signal VSA, and outputs a reset signal VRE that is the sampling signal delayed for a predetermined second delay period DL2. In the exemplary embodiment of the present invention, the first delay period DL1 and the second delay period DL2 are set to be equivalent to each other.

The charging unit 220 generates an on-period voltage VON according to an on-period of the power switch M. The charging unit 220 charges the capacitor 223 with a charging curreit ICH1 during the on-period according to the gate voltage VG to generate an on-period voltage VON, and resets the on-period voltage VON according to the reset signal VRE.

The charging unit 220 includes a current source 221, a charging switch 222, a capacitor 223, and a reset switch 224.

The current source 221 is connected with the voltage VR, and generates the charging current ICH1 using the voltage VR.

The charging switch 222 includes a first terminal connected to the current source 221 and a second terminal connected to the capacitor 223, and is switched according to the gate voltage VG. The charging switch 222 is turned on by an enable-level (i.e., high level in the exemplary embodiment of the present invention) of the gate voltage VG.

During the turn-on period of the charging switch 222, the on-period voltage VON is increased while the capacitor 223 is charged by the charging current ICH1. A second terminal of the capacitor 223 is connected to the ground.

The reset switch 224 includes a first terminal connected to the first terminal of the capacitor 223 and a second terminal connected to the ground, and is switched according to the reset signal VRE. The reset switch 224 is turned on by a high-level reset signal VRE and thus discharges the capacitor 223. Then, the on-period voltage VON is reset to zero voltage.

The sampling unit 230 samples the on-period voltage VON according to the sampling signal VSA, and generates the half-on reference voltage HRV by dividing the sampled voltage into the half.

The sampling unit 230 includes a sampling switch 231, a capacitor 232, and two resistors 233 and 234.

The sampling switch 231 includes a first terminal connected to the on-period voltage VON and a second terminal connected to a node N1, and is switched according to the sampling signal VSA. The sampling switch 231 is turned on by a high-level sampling signal VSA.

The capacitor 232 includes a first terminal connected to the node N1 and a second terminal connected to the ground. The resistor 233 is connected between the node N1 and a node N2, and the resistor 234 is connected between the node N2 and the ground.

A voltage of the node N1 is the same as the on-period voltage VON during the on-period of the sampling switch 231, and the voltage of the node N1 is maintained by the capacitor 232 after the sampling switch 231 is turned off.

The voltage of the node N1 is divided by the resistor 233 and the resistor 234, and the divided voltage becomes a voltage of the node N2, that is, the half-on reference voltage HRV. Since the resistor 233 and the resistor 234 have the same resistance, the half-on reference voltage HRV is the voltage of the node N1, that is, the half of the on-period voltage VON.

As described, the sampling unit 230 samples the half of the on-period voltage VON, increased during the on-period of the power switch M as the half-on reference voltage HRV.

The half-on pulse generation unit 240 compares the half-on reference voltage HRV with the on-period voltage VON, and generates a half-on pulse HOP synchronized at the half-on time point according to the comparison result.

The half-on pulse generation unit 240 includes a comparator 241, an inverter 242, a delay unit 243, and an AND gate 244.

The comparator 241 includes a non-inversion terminal (+) to which the on-period voltage VON is input and an inversion terminal (−) to which the half-on reference voltage HRV is input, and outputs high level when an input of the non-inversion terminal (+) is higher than an input of the inversion terminal (−) and outputs low level in the opposite case.

The inverter 242 receives the output of the comparator 241, and outputs an inverse of the output of the comparator 241.

The delay unit 243 receives the output of the inverter 242, and outputs the output of the inverter 242 after delaying for a third delay period DL3.

The AND gate 244 receives the output of the delay unit 243 and the output of the comparator 241, and generates the half-on pulse HOP by performing an AND operation on the two inputs.

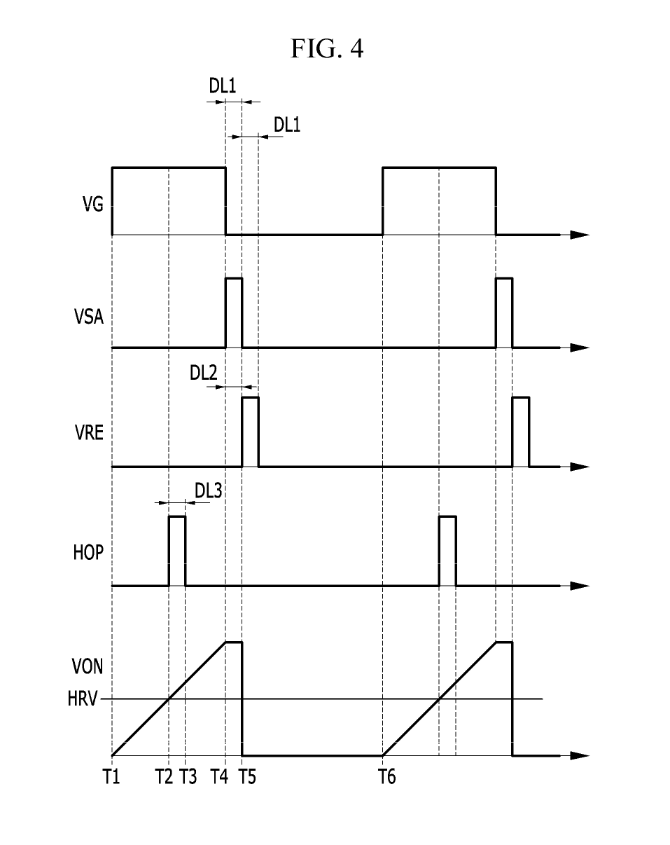

Hereinafter, operation of the half-on detection unit 200 according to the exemplary embodiment of the present invention will be described with reference to FIG. 4.

FIG. 4 is a waveform diagram of the gate voltage, the sampling signal, the reset signal, the on-period voltage, and the half-on pulse according to the exemplary embodiment of the present invention.

As shown in FIG. 4, at a time point T1, the gate voltage VG is increased to high level, and the charging switch 222 is turned on and thus the on-period voltage VON starts to increase.

At a time point T2, the increasing on-period voltage VON reaches the half-on reference voltage HRV and an output of the comparator 241 becomes high level. The half-on reference voltage HRV at the time point T2 corresponds to the half of a voltage charged in the capacitor 223 during an on-period in the previous switching cycle before the time point T1.

Since an output of the inverter 242 is high level and the output of the comparator 241 is increased to high level at the time point T2, a high-level half-on pulse HOP is generated from the AND gate 244 during the third delay period DL3 from the time point T2.

At a time point T3, that is, after the third delay period DL3 is passed from the time point T2, the low-level output of the inverter 243 is input to the AND gate 244, and therefore the half-on pulse HOP becomes low level.

At a time point T4, the gate voltage VG is decreased to low level and the output of the inverter 211 is increased to high level. The output of the delay unit 212 is high level at the time point T4, and therefore the AND gate 213 generates a high-level sampling signal VSA at the time point T4.

The charging switch 222 is turned off at the time point T4, and the on-period voltage VON charged in the capacitor 224 during the turn-on period of the power switch M is maintained with a constant level from the time point T4.

At a time point T5, that is, after the first delay period DL1 is passed from the time point T4, the output of the delay unit 212 becomes low level, and therefore the sampling signal VSA becomes low level. Accordingly, the sampling signal VSA becomes a high-level pulse during a period T4 to T5.

During the period T4 to T5, the sampling switch 231 is turned on and thus the on-period voltage VON is transmitted to the node N1. At the time point T5, the sampling switch 231 is turned off by the low-level sampling signal VSA, and the on-period voltage VON is maintained by the capacitor 232. The on-period voltage VON transmitted to the node N1 at the time point T4 has a level according to an on-period T1 to T5, and the half-on reference voltage HRV is set to the half of the on-period voltage VON.

The delay unit 214 delays the sampling signal VSA for the second delay period DL2 from the time point T4, and outputs the reset signal VRE at the time point T5. The reset switch 224 is turned on at the time point T5 by the reset signal VRE and thus the on-period voltage VON becomes zero voltage.

At a time point T6, the gate voltage VG becomes high level, and the half-on detection unit 200 from the time point T6 iteratively performs operation during the period T1 to T5.

Next, an input current calculation unit 300 according to the exemplary embodiment of the present invention will be described.

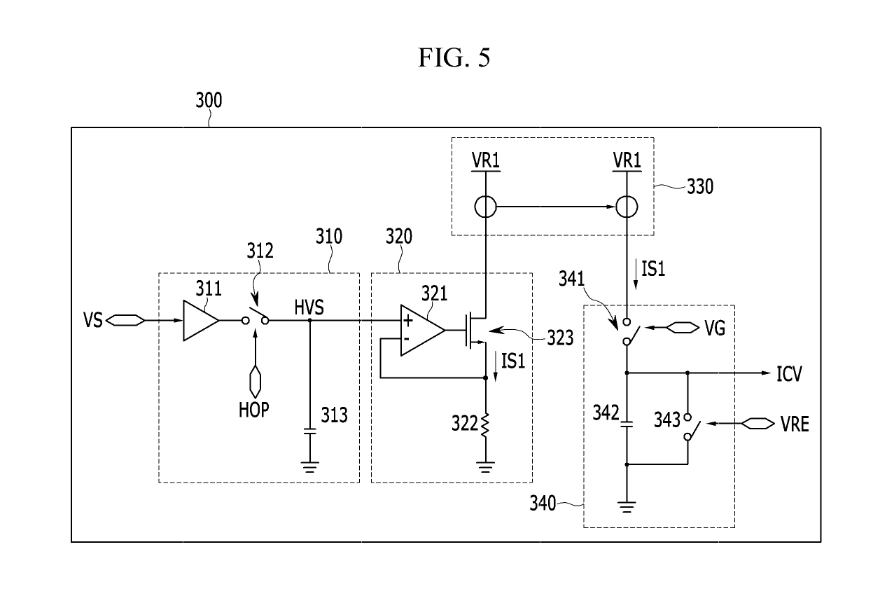

FIG. 5 shows the input current calculation unit according to the exemplary embodiment of the present invention.

The input current calculation unit 300 calculates an input current Iin during the on-period of the power switch M using the half sense voltage HVS and the gate voltage VG. The input current calculation unit 300 generates an input current indicating voltage ICV that indicates the calculated input current Iin.

The input current calculation unit 300 includes a sampling unit 310, a VI converter 320, a current mirror circuit 330, and a charging unit 340.

The sampling unit 310 is synchronized at the half-on time point and generates the half sense voltage HVS by sampling the sense voltage VS. The sampling unit 310 includes a buffer 311, a sampling switch 312, and a capacitor 313.

The buffer 311 is connected between the sense voltage VS and the sampling switch 312. The sampling switch 312 includes a first terminal connected to an output terminal of the buffer 311 and a second terminal connected to a first terminal of the capacitor 313, and is switched according to the half-on pulse HOP. The sampling switch 312 is turned on by the high-level half-on pulse.

A second end of the capacitor 313 is connected to the ground, and the sense voltage VS transmitted through the buffer 311 is stored in the capacitor 313 during the turn-on period of the sampling switch 312. That is, the voltage stored in the capacitor 313 is the half sense voltage HVS.

The VI converter 320 generates a half sense current IS1 by converting the half sense voltage HVS to a current. The VI converter 320 includes an error amplifier 321, a resistor 322, and a transistor 323.

The error amplifier 321 includes a non-inversion terminal (+) to which the half sense voltage HVS is input, an inversion terminal (−) connected a first terminal of the resistor 322 and a source electrode of the transistor 323, and an output terminal connected to a gate electrode of the transistor 323. A second terminal of the resistor 322 is connected to the ground, and a drain electrode of the transistor 323 is connected to a current mirror circuit 330.

The error amplifier 321 amplifies a difference between the half sense voltage HVS and a voltage of the inversion terminal (−) and outputs the amplified value. The output of the error amplifier 321 is supplied to the gate electrode of the transistor 323 such that the half sense current IS1 flowing to the transistor 323 is controlled. Then, the half sense current IS1 is controlled to make the voltage of the inversion terminal (−) to be equivalent to the half sense voltage HVS.

The current mirror circuit 330 mirrors the half sense current IS1 and transmits the mirrored current to the charging unit 340. The current mirror circuit 330 is connected to a voltage VR1 to receive a voltage for operation.

The charging unit 340 generates the input current indicating voltage ICV using the half sense current IS1. The charging unit 340 includes a charging switch 341, a capacitor 342, and a reset switch 343.

The charging switch 341 includes a first terminal connected to the current mirror circuit 330 and a second terminal connected to a first terminal of the capacitor 342. The charging switch 341 is switched according to the gate voltage VG. During the turn-on period of the power switch M, the capacitor 342 is charged by the half sense current IS1.

A second terminal of the capacitor 342 is connected to the ground, the reset switch 343 is connected to both terminals of the capacitor 342 in parallel, and the reset switch 343 is switched according to the reset signal VRE. Thus, the reset switch 343 is turned on by a high-level reset signal VRE.

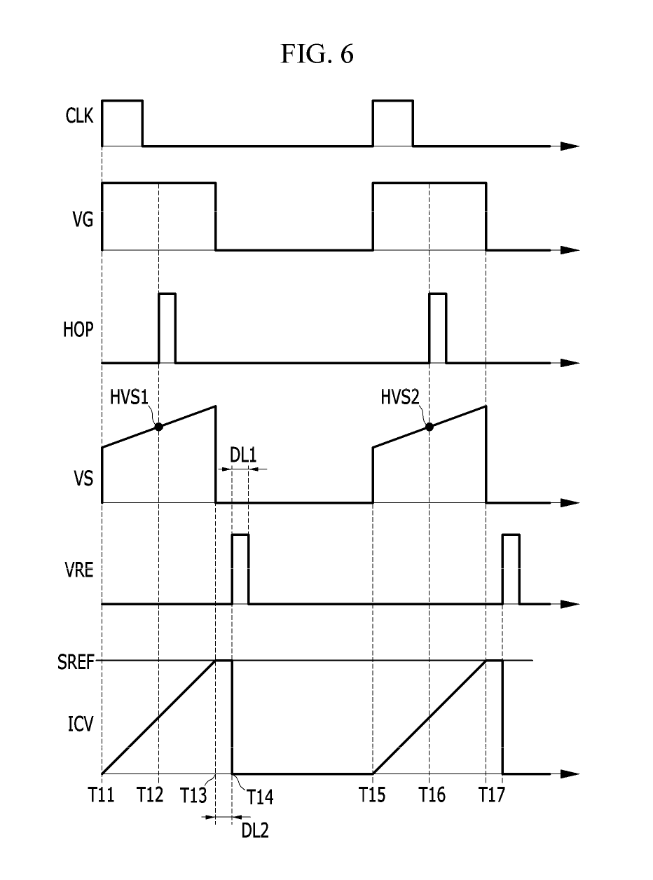

Hereinafter, operation of the input current calculation unit 300 will be described with reference to FIG. 6.

FIG. 6 is a waveform of the gate voltage, the half-on pulse, the sense voltage, the reset pulse, and the input voltage indicating voltage according to the exemplary embodiment of the present invention.

As shown in FIG. 6, at a time point T11, the clock signal CLK is increased to high level, the gate voltage VG is increased to high level, and the charging switch 341 is turned on. The capacitor 342 is charged during a period T11 to T12 by the half sense current IS1 that depends on the half sense voltage HVS sampled by the sampling unit 313 before the time point T11.

At a time point T12, the half-on pulse HOP is increased to high level and the sampling switch 312 is turned on and thus a sense voltage VS at the time point T12 is stored in the capacitor 313. At the time point T12, the half sense voltage HVS has a level of HVS1. From the time point T12, the half sense current IS1 is determined according to the HVS1.

When the input current indicating voltage ICV reaches the reference sine wave SREF at a time point T13, the gate voltage VG is decreased to low level and the power switch M is turned off. During a period T12 to T13, the half sense current IS1 that depends on the HVS1.

The sense voltage VS is not generated from the time point T13, and the reset signal VRE is generated at a time point that is after the second delay period DL2 is delayed from the time point T13. The reset switch 343 is turned on by the reset signal VRE and thus the input current indicating voltage ICV becomes zero voltage.

At a time point T15, the clock signal CLK is increased to high level and the gate voltage VG is increased to high level and thus the power switch M is turned on. Then, the half sense voltage HVS is sampled by the sampling unit 310 at a time point T16 that the half on pulse HOP is generated. In this case, the half sense voltage HVS has a level of HVS2. When the input current indicating voltage ICV increasing from the time point T15 reaches the reference sine wave SREF at a time point T17, the power switch M is turned off.

The half sense current IS1 is a current depending on the HVS1 during a period T15 to T16 and depending on the HVS2 during a period T16 to T17. Since half sense voltages HVS sampled in adjacent switching cycles are equivalent to each other, a half sense current IS1 that depends on a half sense voltage HVS sampled in the previous switching cycle may be used in generation of the input current indicating voltage ICV.

In FIG. 6, the reference sine wave SREF is illustrated as a straight line because the two switching cycles are short time periods. As previously stated, the reference sine wave SREF is a sine wave according to the exemplary embodiment of the present invention.

As described, in the exemplary embodiment of the present invention, the half-on time point is detected and the sense voltage VS at the half-on time point is sampled to estimate a middle value of the input current Iin flowing during the turn-on period of the power switch M, and the input current Iin flowing during the turn-on period can be calculated by multiplying the turn-on period to the estimated middle value. The calculated input current Iin having the reference sine wave SREF by switching operation of the power switch M, and accordingly power factor correction can be enhanced.

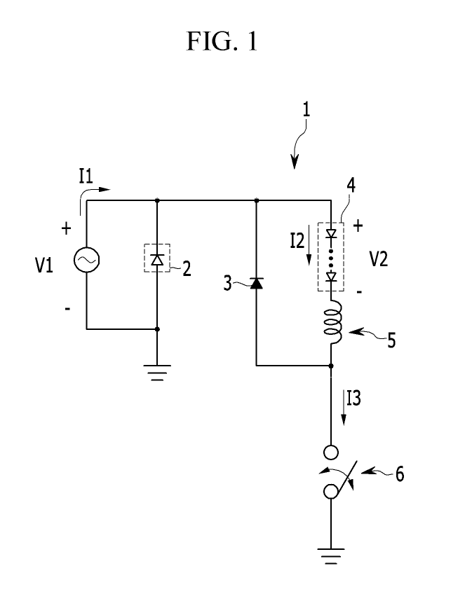

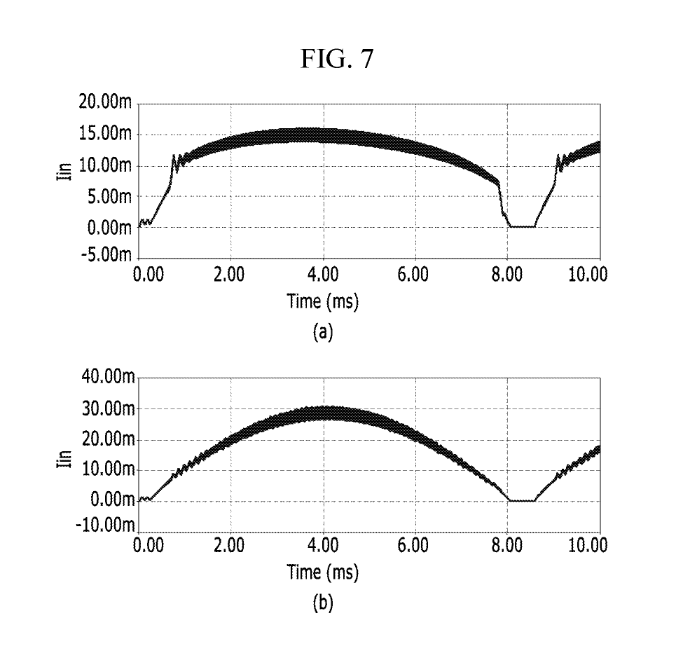

FIG. 7 shows comparison between an input current according to the conventional art shown in FIG. 1 and an input current according to the exemplary embodiment of the present invention.

As shown in (a) of FIG. 7, the input current according to the conventional art does not have a sine wave. On the contrary, the input current Iin according to the exemplary embodiment of the present invention, shown in (b) of FIG. 7 has a full-wave rectified sine wave.

While this invention has been described in connection with what is presently considered to be practical exemplary embodiments, it is to be understood that the invention is not limited to the disclosed embodiments, but, on the contrary, is intended to cover various modifications and equivalent arrangements included within the spirit and scope of the appended claims.

### DESCRIPTION OF SYMBOLS

buck converter 1, 10, LED string 4, 20, switch 6, diode (3, FRD) rectification circuit 2, 30, EMI filter 40, inductor(L, L1, L2), power switch M

sense resistor RS, switch controller 100, recitification diode 31-34 capacitor (C1, C2, 223, 232, 342), sine wave generation unit 110 off comparator 120, oscillator 130, SR flip-flop 140

gate driving unit 150, half-on detection unit 200, input current calculation unit 300

sampling/reset signal generation unit 210, charging unit 220 and 340

sampling unit 230 and 310, half-on pulse generation unit 240, inverter 211 and 242

delay unit 212, 213, and 243, AND gate 213 and 244, current source 221

charging switch 222 and 341, reset switch 224 and 343

sampling switch 231 and 312, resistor 233, 234, and 322, comparator 241

VI converter 320, current mirror circuit 330, buffer 311, error amplifier 321

transistor 323

What is claimed is:

1. A power supply comprising:
a rectification circuit coupled to an AC input;
a power switch configured to receive a current generated by the AC input and passed through and rectified by the rectification circuit during a turn-on period of the power switch; and
a switch controller configured to detect a half-on time point, the half-on time point corresponding to an intermediate time point of the turn-on period of the power switch, and calculate the AC input current based on a detected sense voltage based on a current flowing to the power switch during the turn-on period at the half-on time point and the turn-on period, the switch controller further being configured to control the AC input current to have a reference sine wave,
wherein the reference sine wave follows a sine wave that is full-wave rectified from the AC input.

2. The power supply of claim 1, wherein the switch controller comprises an input current calculation unit configured to calculate the AC input based on a half sense voltage generated based on a sampling of the sense voltage at the half-on time point and the turn-on period of the power switch.

3. The power supply of claim 1, wherein the switch controller comprises a half-on detection unit configured to detect a half-on time point based on a comparison of a half-on reference voltage, the half-on reference voltage being based on a sampled voltage that is the half of a voltage charged during a turn-on period in a previous switching cycle of the power switch, with a voltage charged during a turn-on period of a present switching cycle, the half-on time point being based on a sensed time point that the voltage charged from the turn-on period reaches the half-on reference voltage.

4. The power supply of claim 3, wherein the half-on detection unit comprises:
a sampling/reset signal generation unit configured to generate a sampling signal for commanding sampling and a reset signal for commanding reset, the sampling and reset signals being synchronized at a turn-off time point of the power switch;
a charging unit configured to generate an on-period voltage based on the turn-on period of the power switch;
a sampling unit configured to sample the on-period voltage based on the sampling signal and generate the half-on reference voltage based on a division of the sampled on-period voltage in half; and
a half-on pulse generation unit configured to generate a half-on pulse synchronized at a half-on time point based on a comparison of the half-on reference voltage with the on-period voltage.

5. The power supply of claim 4, wherein the sampling/reset signal generation unit comprises:
an inverter configured to output an inverted level of a gate voltage configured to control switching operation of the power switch;
a first delay unit configured to receive and output the gate voltage after a predetermined first delay period;
an AND gate configured to receive outputs of the inverter and first delay unit and perform an AND operation of the outputs to generate a sampling signal; and
a second delay unit configured to receive the sampling signal and output the sampling signal after a predetermined second delay period.

6. The power supply of claim 4, wherein the charging unit comprises:
a capacitor;
a current source configured to generate a charging current;
a charging switch coupled between the current source and the capacitor and being configured to be turned on during the turn-on period of the power switch; and
a reset switch coupled to the capacitor in parallel and being configured to be switched based on the reset signal.

7. The power supply of claim 4, wherein the sampling unit comprises:
a sampling switch configured to be switched based on the sampling signal and further configured to transmit the on-period voltage to a first node;
a capacitor coupled between the first node and a ground; and
a first resistor coupled between the first node and a second node; and
a second resistor coupled between the first node and the ground,
wherein a voltage of the second node is the half-on reference voltage.

8. The power supply of claim 4, wherein the half-on pulse generation unit comprises:
a comparator configured to output a voltage based on a comparison between the on-period voltage and the half-on reference voltage;
an inverter configured to receive the comparator output and further output an inverse of the output of the comparator;
a delay unit configured to receive and output the inverted output of the inverter after a third delay period; and
an AND gate configured to receive the outputs of the comparator and delay unit and perform an AND operation on the outputs to generate the half-on pulse.

9. The power supply of claim 3, wherein the switch controller further comprises an input current calculation unit configured to generate a half sense current based on a half sense voltage sampled from the sense voltage at every half-on time point and further generate an input current indicating voltage indicating the input current based on the half sense current during the turn-on period of the present switching cycle.

10. The power supply of claim 9, wherein the input current calculation unit comprises:
a sampling unit synchronized at the half-on time point and configured to sample the sense voltage and generate the half sense voltage based on the sampled sense voltage;
a VI converter configured to convert the half sense voltage and generate a half sense current based on the converted half sense voltage;
a charging unit configured to generate the input current indicating voltage based on the half sense current; and
a current mirror circuit configured to mirror the half sense current and transmit the mirrored current to the charging unit.

11. The power supply of claim 10, wherein the sampling unit comprises:
a buffer configured to transmit the sense voltage;
a capacitor; and
a sampling switch coupled between an output terminal of the buffer and the capacitor, and being synchronized at the half-on time point and configured to transmit the sense voltage to the capacitor,
wherein a voltage charged in the capacitor is the half-on reference voltage.

12. The power supply of claim 10, wherein the VI converter comprises:
an error amplifier including a first terminal configured to receive the half sense voltage as input, a second terminal, and an output terminal;
a resistor coupled between the second terminal of the error amplifier and the ground; and
a transistor including a first electrode coupled to the current mirror circuit, a second electrode coupled to the second terminal of the error amplifier, and a gate electrode coupled to the output terminal of the error amplifier.

13. The power supply of claim 10, wherein the charging unit comprises:
a capacitor;
a charging switch coupled between the current mirror and the capacitor and being configured to be turned on during the turn-on period of the power switch; and
a reset switch coupled to the capacitor in parallel and being configured to be switched based on the reset signal,
wherein, during the turn-on period of the charging switch, the capacitor is configured to be charged by the half sense current and wherein a voltage charged in the capacitor is the input current indicating voltage.

14. The power supply of claim 9, wherein the switch controller is configured to turn off the power switch at a time point that the input current indicating voltage reaches the reference sine wave.

15. The power supply of claim 1, wherein the switch controller is configured to detect one cycle of the input voltage based on sensing a zero voltage crossing time point of the input voltage and generation of the reference sine wave that is a full wave rectified sine wave of the same cycle of one cycle of the input voltage.

16. A method of driving a power switch, the method comprising:
receiving an input current through a power switch from an AC input during a turn-on period of the power switch;
detecting a half-on time point corresponding to an intermediate time point of the turn-on period of the power switch;
generating a half sense voltage based on a sampling of a sense voltage based on the current flowing to the power switch during the turn-on period at the half-on time point;
calculating the input current based on the turn-on period and the half sense voltage; and
switching the power switch to control the calculated input current to have a reference sine wave that is a full wave rectified sine wave.

17. The driving method of claim 16, wherein the detecting the half-on time point comprises:
sampling a voltage that is the half of a voltage charged during a turn-on period of a previous switching cycle of the power switch as a half-on reference voltage; and
sensing a time point that a voltage charged during a turn-on period of the present switching cycle reaches the half-on reference voltage as the half-on time point.

18. The driving method of claim 17, wherein the calculating the input current comprises:
converting the half sense voltage into a half sense current; and
generating an input current indicating voltage indicating the input current based on the half sense current during the turn-on period of the present switching cycle.

19. A switch controller of a power supply configured to convert an AC input based on a switching operation of a power switch, the switch controller comprising:
a half-on detection unit configured to detect a half-on time point based on a comparison of a half-on reference voltage, the half-on reference being based on a sampled voltage that is the half of a voltage charged during a turn-on period of a previous switching cycle of the power switch, with a voltage charged during a turn-on period of a present switching cycle, the half-on time point being based on a sensed time point that the voltage charged from the turn-on period reaches the half-on reference voltage; and
an input current calculation unit configured to calculate an input current of the AC input based on a product of multiplying the turn-on period of the present switching cycle and a half sense voltage sampled from a sense voltage at every half-on time point,
wherein the input current includes a current flowing through the power switch from the AC input during the turn-on period of the power switch.

20. The switch controller of claim 19, wherein the half-on detection unit comprises:
a sampling/reset signal generation unit configured to generate a sampling signal for commanding sampling and a reset signal for commanding reset, the sampling and reset signals being synchronized at a turn-off time point of the power switch;
a charging unit configured to generate an on-period voltage based on the turn-on period of the power switch;
a sampling unit configured to sample the on-period voltage based on the sampling signal and generate the half-on reference voltage based on a division of the sampled on-period voltage in half; and
a half-on pulse generation unit configured to generate a half-on pulse synchronized at a half-on time point based on a comparison of the half-on reference voltage with the on-period voltage.

21. The switch controller of claim 19, wherein the input current calculation unit comprises:
a sampling unit being synchronized at the half-on time point and configured to sample the sense voltage and generate the half sense voltage based on the sampled sense voltage;
a VI converter configured to convert the half sense voltage and generate a half sense current based on the converted half sense voltage;
a charging unit configured to generate an input current indicating voltage based on the half sense current; and
a current mirror circuit configured to mirror the half sense current and transmit the mirrored current to the charging unit.
